(19) United States
(12) Patent Application Publication
(10) Pub. No.: US 2021/0111041 A1
(43) Pub. Date: Apr. 15, 2021

(54) STAGE CLEANING METHOD, STAGE CLEANING MEMBER, METHOD FOR PRODUCING STAGE CLEANING MEMBER, AND INSPECTION SYSTEM

(71) Applicant: TOKYO ELECTRON LIMITED, Tokyo (JP)

(72) Inventors: Jun MOCHIZUKI, Yamanashi (JP); Hiroshi YAMADA, Yamanashi (JP)

(21) Appl. No.: 16/496,366

(22) PCT Filed: Feb. 8, 2018
(86) PCT No.: PCT/JP2018/004405

§ 371 Date: Sep. 20, 2019

(30) Foreign Application Priority Data
Mar. 21, 2017 (JP) 2017-054215

(51) Int. Cl. H01L 21/67; B08B 5/02; B08B 1/00; B08B 7/00; H01L 21/683

(52) U.S. Cl. CPC H01L 21/67028; B08B 5/02; H01L 21/67242; B08B 7/0028; H01L 21/6838; B08B 1/002

(57) ABSTRACT

A cleaning wafer is provided for cleaning a surface of a chuck top by being mounted on the chuck top, the chuck top having a gas supply port and a gas exhaust port on the surface thereof and being configured to mount a substrate thereon. The cleaning wafer has a plate-shaped main body and an inlet/outlet path which is provided in the main body, and to which gas is supplied from the gas supply port and from which the gas is exhausted to the exhaust port. Dust attached to the surface of the chuck top is removed by the gas being supplied to the inlet/output path and exhausted from the inlet/output path.

### TECHNICAL FIELD

The present invention relates to a stage cleaning method and a stage cleaning member for cleaning a stage on which a substrate is mounted, a method for producing a stage cleaning member, and an inspection system.

### BACKGROUND

In a semiconductor device manufacturing process, an electrical inspection of a plurality of semiconductor elements (hereinafter, simply referred to as “devices”) formed on a semiconductor wafer is performed after all processes are performed on the semiconductor wafer (hereinafter, simply referred to as “wafer”). A prober is used as an apparatus for performing such an electrical inspection. The prober includes a probe card disposed to face the wafer. The probe card has a plate-like base and contact probes (probe needles) that are columnar contact terminals arranged at the base to face electrodes of the devices on the wafer.

In the prober, the contact probes of the probe card are brought into contact with the electrodes of the devices by pressing the wafer against the probe card using a stage (chuck) for attracting and holding the wafer, and electricity is made to flow from the contact probes to the electrodes to inspect electrical characteristics such as conduction states of the devices and the like.

In an inspection device such as a prober, the wafer may be contaminated by adhesion of dust such as particles or the like to the stage for attracting and holding the wafer. Therefore, in a conventional case, the device is periodically stopped and an operator removes dust using “hand wiping” or “air blowing”.

Although it is not a technique related to the inspection device, there is suggested a technique for automatically transferring a cleaning wafer having a dot pattern (irregularities) onto a wafer mounting table, performing suction through a vacuum hole of the wafer mounting table to make the cleaning wafer sweep the wafer mounting table, collecting foreign substances in recesses of the cleaning wafer, and scraping off the foreign substances without stopping a device (see Patent Document 1).

There are also proposed techniques for removing particles by mounting a plate on a stage and supplying gas to a gap between the plate and the stage (see Patent Documents 2 and 3).

### PRIOR ART

Patent document 1: Japanese Patent Application Publication No. 2009-141384

Patent document 2: Japanese Patent Application Publication No. 2010-204650

Patent document 3: Japanese Patent Application Publication No. 2016-050349

In the technique of Patent Document 1, although foreign substances (dust) are scraped using the irregularities of the cleaning wafer, the foreign substances (dust) may not be sufficiently removed. Further, in the techniques of Patent Documents 2 and 3, dust may scatter due to the supplied gas and the scattered dust may be adhered again.

In view of the above, the present invention provides a technique capable of effectively removing dust adhered to a stage while preventing scattering of the dust without stopping a device.

### SUMMARY

In accordance with a first aspect of the present invention, there is provided a stage cleaning member for cleaning a surface of a stage by being mounted on the stage, the stage having a gas supply port and a gas exhaust port on a surface thereof and being configured to mount a substrate thereon, comprising a plate-shaped main body and an inlet/outlet path disposed in the main body, to which gas is supplied from the gas supply port and from which the gas is exhausted to the gas exhaust port, wherein dust adhered to the surface of the stage is removed by the gas being supplied to the inlet/outlet path and exhausted from the inlet/outlet path.

In the first aspect, the main body may be vacuum-attracted to the stage.

The inlet/outlet path may include a recess below a bottom surface of the main body in a situation of being mounted on the stage, and dust adhered to the surface of the stage which corresponds to the recess may be removed by air flow that is generated in the recess when the gas is supplied from the gas supply port to the recess and exhausted from the recess to the gas exhaust port.

In this case, the inlet/outlet path may further include a gas diffusion space formed in the main body to allow diffusion of the gas supplied from the gas supply port and a plurality of gas injection holes for injecting the gas from the gas diffusion space to the recess, and the dust adhered to the surface of the stage which corresponds to the recess may be removed by the air flow supplied from the gas diffusion space to the recess through the gas injection holes and discharged to the gas exhaust port. Further, the stage cleaning member may further comprise a brush disposed in the recess. The brush may be vibrated by the air flow that is generated in the recess when the gas is supplied from the gas supply port to the recess and exhausted from the recess to the gas exhaust port, the dust adhered to the surface of the stage which corresponds to the recess may be removed by brushing, and the removed dust may be discharged to the gas exhaust port by the air flow generated in the recess.

The inlet/outlet path may include a recess formed below a bottom surface of the main body in a situation of being mounted on the stage and an adsorption member which is disposed in the recess and has an adsorption surface facing the surface of the stage. Further, the adsorption member may be vertically moved by adjusting supply of the gas from the gas supply port to the inlet/outlet path or exhaust of the gas from the gas exhaust port to adsorb and remove the dust adhered to the surface of the stage.

In this case, the adsorption member may have an elevation plate and an adhesive film formed on a bottom surface of the elevation plate, and the dust adhered to the surface of the stage may be adsorbed to and removed by the adhesive film. Further, the elevation plate may be connected to the main body via plate springs and may be vertically moved via the plate springs.

In accordance with a second aspect of the present invention, there is provided a stage cleaning method for cleaning a surface of a stage, the stage having a gas supply port and a gas exhaust port on the surface and being configured to mount a substrate thereon, the method comprising: mounting a stage cleaning member on the stage, the stage cleaning member having a plate-shaped main body and an inlet/outlet path to which gas is supplied from the gas supply port and from which the gas is exhausted to the gas exhaust port, the inlet/outlet path being disposed in the main body; and removing dust adhered to the surface of the stage using the gas being supplied to the inlet/outlet path and exhausted from the inlet/outlet path.

In accordance with a third aspect of the present invention, there is provided a method for producing the stage cleaning member described in the first aspect of the present invention, wherein a plurality of thin plates are formed in a predetermined shape, stacked, and diffusion-bonded by heating and pressing to form the stage cleaning member having a desired shape.

In accordance with a fourth aspect of the present invention, there is provided an inspection system, comprising: an inspection device having a stage which is configured to mount a substrate thereon and being configured to inspect the substrate on the stage; a substrate accommodation part configured to accommodate the substrate; a stage cleaning member accommodation part configured to accommodate a stage cleaning member for cleaning the stage and the substrate on the stage; and a transfer device configured to transfer the substrate accommodated in the substrate accommodation part and the stage cleaning member accommodated in the stage cleaning member accommodation part onto the stage, wherein the stage has a gas supply port and a gas exhaust port on a surface thereof, the stage cleaning member described in the first aspect of the present invention is used as the stage cleaning member, and the stage cleaning member is transferred onto the stage by the transfer device at the time of cleaning the surface of the stage.

According to the aspects of the present invention, it is possible to effectively remove dust adhered to a stage while preventing scattering of the dust without stopping a device, using a stage cleaning member comprising a plate-shaped main body and an inlet/outlet path disposed in the main body, to which gas is supplied from the gas supply port and from which the gas is exhausted to the gas exhaust port, wherein dust adhered to the surface of the stage is removed by the gas being supplied to the inlet/outlet path and exhausted from the inlet/outlet path.

### BRIEF DESCRIPTION OF THE DRAWINGS

FIG. 1 is a horizontal cross-sectional view schematically showing an exemplary configuration of an inspection system.

FIG. 2 shows a schematic configuration of an inspection device.

FIG. 3 is a cross-sectional view showing a state in which a cleaning wafer according to a first embodiment is mounted on a chuck top.

FIG. 4 is a cross-sectional view showing a state in which a cleaning wafer according to a second embodiment is mounted on the chuck top.

FIG. 5 is a cross-sectional view showing a state in which a cleaning wafer according to a third embodiment is mounted on the chuck top.

FIG. 6 is a cross-sectional view showing a state in which a cleaning wafer according to a fourth embodiment is mounted on the chuck top.

FIG. 7 is an exploded perspective view for explaining a configuration of an elevation member used for the cleaning wafer according to the fourth embodiment.

FIGS. 8A and 8B explain a cleaning operation of the cleaning wafer according to the fourth embodiment.

### DETAILED DESCRIPTION

Hereinafter, embodiments of the present invention will be described in detail with reference to the accompanying drawings.

<Inspection System>

First, an example of an overall configuration of an inspection system to which a stage cleaning method of the present invention is applied will be described.

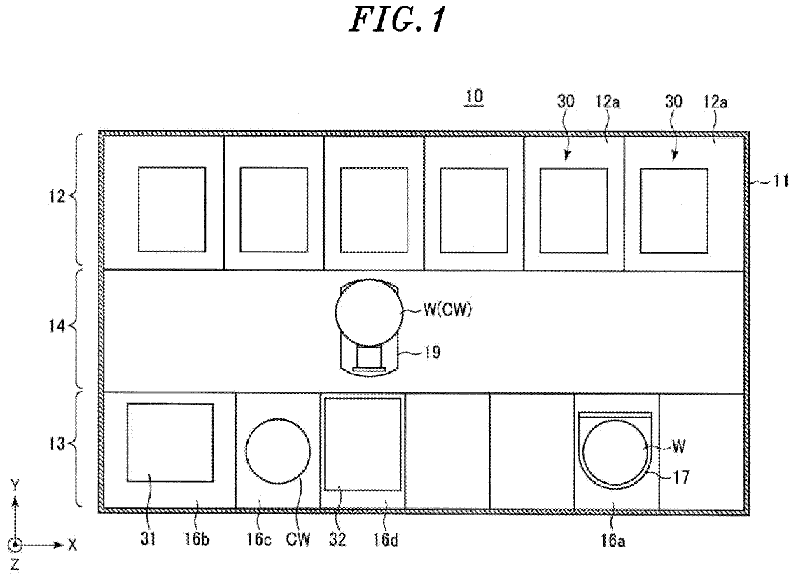

FIG. 1 is a horizontal cross-sectional view schematically showing an exemplary configuration of the inspection system.

Referring to FIG. 1, an inspection system 10 includes a housing 11 having an inspection area 12 for inspecting electrical characteristics of semiconductor devices of a wafer W, a loading/unloading area 13 for loading/unloading the wafer W or the like into/from the inspection area 12, and a transfer area 14 disposed between the inspection area 12 and the loading/unloading area 13.

The inspection area 12 has a plurality of (six in this example) inspection rooms 12a arranged along the X direction. An inspection device (probe) 30 is disposed in each inspection room 12a.

The loading/unloading area 13 is divided into a plurality of ports including a wafer loading/unloading port 16a accommodating a container, e.g., a FOUP 17 accommodating a plurality of wafers W, a loader port 16b accommodating a loader 31 into/from which a probe card 23 is loaded/unloaded, a cleaning wafer mounting port 16c for mounting a cleaning wafer (stage cleaning member) CW, and a control unit accommodation port 16d accommodating a control unit 32 for controlling operations of components of the inspection system 10. One or a plurality of cleaning wafers CW may be accommodated in the cleaning wafer mounting port 16c in advance, or may be loaded into the cleaning wafer mounting port 16c from outside at the timing of cleaning.

A movable transfer robot 19 is disposed in the transfer area 14. The transfer robot 19 transfers the wafer W from the wafer loading/unloading port 16a of the loading/unloading area 13 to the chuck top (stage) for attracting and holding the wafer in each inspection device 30, and transfers the wafer W having devices whose electrical characteristics have been inspected from the chuck top of the corresponding inspection device 30 to the wafer loading/unloading port 16a. In the case of cleaning the chuck top, the transfer robot 19 transfers the cleaning wafer CW from the cleaning wafer mounting port 16c of the loading/unloading area 13 to the chuck top of each inspection device 30, and transfers the cleaning wafer W from the chuck top to the cleaning wafer mounting port 16c after the cleaning. Further, the transfer robot 19 transfers the probe card 18 requiring maintenance from each inspection device 30 to the loader 31 of the loader port 16b, and transfers a new probe card 23 or a probe card 23 that has been subjected to maintenance to each inspection device 30.

The control unit 32 includes a main controller having a CPU and configured to control the respective components of the inspection system 10, e.g., the respective parts of each inspection device 30, the transfer device 19, and the like, an input device (keyboard, mouse or the like), an output device (printer or the like), a display device (display or the like), and a storage device (storage medium). The main controller of the control unit 32 causes the inspection system 10 to execute a predetermined operation based on, e.g., a processing recipe stored in a storage medium built in the storage device or in a storage medium set in the storage device.

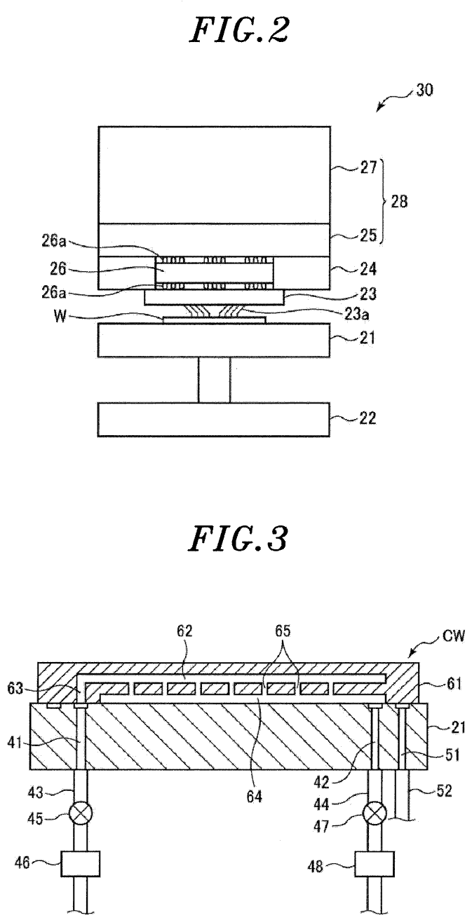

As shown in FIG. 2, the inspection device 30 includes: a chuck top (stage) 21 for attracting and holding the wafer W by vacuum attraction; an aligner 22 for moving the chuck top 21 in the X, Y, Z, and θ directions using an XY table mechanism, a Z-direction moving mechanism, and a θ-direction moving mechanism (all not shown) to position the wafer W at a predetermined position; the probe card 23 disposed opposite to the chuck top 21; a support plate 24 for supporting the probe card 23; a tester motherboard 25 disposed on the support plate 24; a contact block 26 that connects the tester motherboard 25 and the probe card 23; and a test head 27 disposed on the tester motherboard 25. The tester motherboard 25 and the test head 27 constitute a tester 28. The probe card 23 has a plurality of probes 23a to be in contact with the electrodes of devices formed on the wafer W. A plurality of pogo pins 26a are disposed on an upper surface and a bottom surface of the contact block 26 to electrically connect the probe card 23 and the tester motherboard 25.

Then, electrical signals are applied from a tester module board (not shown) in the test head 27 to the devices of the wafer W through the tester motherboard 25 and the probes 23a of the probe card 23, and the electrical characteristics are inspected using electrical signals returned to the tester module board.

When the inspection is performed in a state where the probes 23a are in contact with the electrodes of the devices formed on the wafer W, an inspection space between the support plate 24 and the chuck top 21 is sealed with a sealing member or a bellows. By depressurizing the inspection space, the chuck top 21 may be adhered to the support plate 24. In that case, one aligner 22 may be shared by a plurality of inspection devices 30. The inspection devices 30 may be disposed in multiple stages in the inspection room 12a. In this case, the transfer area 14 and the transfer robot 19 are arranged on each stage.

The inspection system 10 configured as described above performs an operation of transferring the wafer W from the wafer loading/unloading port 16a to each inspection device 30 using the transfer robot 19 and an operation of returning the wafer W whose electrical characteristics are inspected to the wafer loading/unloading port 16a using the transfer robot 19 simultaneously and continuously.

Then, at a predetermined timing, the cleaning wafer CW is transferred from the cleaning wafer mounting port 16c onto the chuck top 21 of the inspection device 30 by the transfer robot 19, and the upper surface of the chuck top 21 is cleaned. After the cleaning, the cleaning wafer CW is returned to the cleaning wafer mounting port 16c by the transfer robot 19. At this time, a chuck top 21 of a specific inspection device 30 may be cleaned, or the chuck tops 21 of all the inspection devices 30 may be cleaned consecutively.

By using the cleaning wafer CW at an appropriate timing, the chuck top 21 can be cleaned on-line without an operator's “hand wiping” or “air blowing”.

<Cleaning Wafer>

Next, the cleaning wafer CW will be described.

### First Embodiment of Cleaning Wafer

First, a first embodiment of the cleaning wafer CW will be described.

FIG. 3 is a cross-sectional view showing a state in which the cleaning wafer CW according to the first embodiment is mounted on the chuck top 21.

A gas supply passage 41 is disposed at a peripheral portion of the chuck top 21 to penetrate therethrough in a vertical direction. A gas discharge passage 32 is disposed at an opposite side of the peripheral portion of the chuck top 21 where the gas supply passage 41 is disposed to penetrate therethrough in the vertical direction. A gas supply port where the gas supply passage 41 is opened and a gas exhaust port where the gas discharge passage 42 is opened are formed in the surface of the chuck top 21. A gas supply line 43 is connected to the gas supply passage 41, and a gas discharge line 44 is connected to the gas discharge passage 42. The gas supply line 43 is provided with an electromagnetic valve 45 and a filter 46 for controlling the supply side. The gas discharge line 44 is provided with an electromagnetic valve 47 and a filter 48 for controlling the exhaust side. Further, a gas exhaust passage 51 for vacuum-attracting the cleaning wafer CW is formed in the chuck top 21 to penetrate therethrough in the vertical direction. A gas exhaust line 52 is connected to the gas exhaust passage 51. A vacuum pump (not shown) is connected to the gas discharge line 43 and the gas exhaust line 52.

During the inspection of the wafer W, both of the gas discharge passage 42 and the gas exhaust passage 51 are used as a vacuum exhaust line for attracting the wafer W having a predetermined diameter. Although air is preferably used as the gas, another gas such as nitrogen gas or the like may be used. The gas supply passage 41 may be formed in a conventional chuck top and connected to an airline or the like in a factory. Such a chuck top may be used as the chuck top 21.

The cleaning wafer CW of the present embodiment has a plate-shaped main body 61 and a disc-shaped gas diffusion space 62 disposed at the center of the main body 61. At the peripheral portion of the main body 61, a gas inlet line 63 connected to the gas supply port of the gas supply passage 41 on the surface of the chuck top 21 extends upward from the bottom surface of the main body 61 and is connected to the gas diffusion space 62. At the central portion of the bottom surface of the main body 61, a cylindrical groove-shaped recess 64 is formed in a region including the gas exhaust port of the gas discharge passage 42 on the surface of the chuck top 21. A plurality of gas injection holes 65 are formed in the gas diffusion space 62 to reach the recess 64. The gas diffusion space 62, the gas inlet line 63, the recess 64, and the gas injection holes 65 form an inlet/outlet path.

The cleaning wafer CW preferably has the same disc shape as that of the wafer W. The transfer robot 19 can easily transfer the cleaning wafer CW because the cleaning wafer W has the same shape as that of the wafer W. However, the shape of the cleaning wafer CW is not limited to the disc shape. The thickness of the cleaning wafer CW may be greater than that of the wafer W as an inspection target object because the gas channel is formed therein. The cleaning wafer W may have a thickness that allows the cleaning wafer W to be transferred by the transfer robot 19.

When the cleaning wafer CW is mounted on the chuck top 21, the bottom portion of the main body 61 which is disposed at the outer side of the recess 64 is vacuum-attracted to the chuck top 21, and the recess 64 becomes a sealed space.

Therefore, the gas introduced from the gas supply line 43 to the gas inlet line 63 in the cleaning wafer CW through the gas supply passage 41 is diffused in the gas diffusion space 62, and is uniformly supplied from the gas injection holes 65 to the surface of the chuck top 21 through the recess 64. Then, the gas is discharged from the recess 64 through the gas discharge passage 42 and the gas discharge line 44.

Therefore, the gas introduced from the gas supply passage 41 to the gas inlet line 63 is supplied to the recess 64 in contact with the chuck top 21 and then to the surface of the chuck top 21. Next, the gas is discharged from the recess 64 through the gas discharge passage 42. Accordingly, air flow directed toward the gas discharge passage 42 is generated in the recess 64. Dust on the surface of the chuck top 21 in contact with the recess 64 can be effectively removed by the air flow. Since the gas is uniformly supplied in a shower pattern from the gas injection holes 65 to the surface of the chuck top 21 inside the main body 61, the entire surface of the chuck top 21 can be uniformly cleaned. Further, since the air flow is generated only in the cleaning wafer CW, dust does not scatter.

### Second Embodiment of Cleaning Wafer

Next, a second embodiment of the cleaning wafer CW will be described.

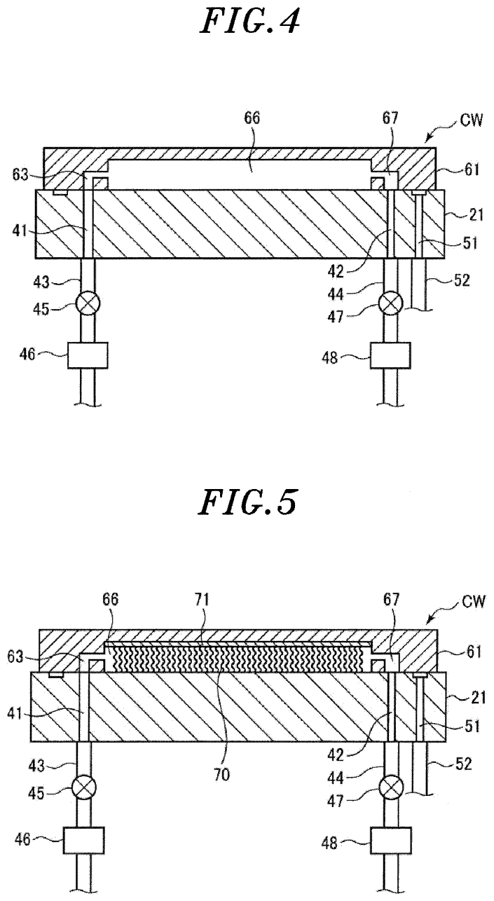

FIG. 4 is a cross-sectional view showing a state in which the cleaning wafer CW according to the second embodiment is mounted on the chuck top 21.

The cleaning wafer CW of the present embodiment has a main body 61 having the same disc shape as that of the wafer. A cylindrical groove-shaped recess 66 is formed at the center of the bottom surface of the main body 61. The same gas inlet line 63 as that of the first embodiment is connected to the recess 66. A gas channel 67 that connects the recess 66 and the bottom surface of the main body 61 is disposed at a portion corresponding to the gas discharge passage 42 of the main body 61. The outer peripheral portion of the bottom portion of the main body 61 which is disposed at the outer side of the recess 64 is vacuum-attracted to the chuck top 21, and the recess 66 becomes a sealed space. The gas inlet line 63, the recess 66, and the gas channel 67 form an inlet/outlet path.

Therefore, the gas introduced from the gas supply line 43 to the gas inlet line 63 in the cleaning wafer CW through the gas supply passage 41 reaches the recess 66 and is supplied to the surface of the chuck top 21. Then, the gas is supplied from the recess 66 to the gas discharge passage 42 through the gas channel 67 and is discharged through the gas discharge passage 42 and the gas discharge line 44.

The gas introduced from the gas supply passage 41 to the gas inlet line 63 is supplied to the recess 66 facing the chuck top 21 and is discharged from the recess 66 through the gas channel 67 and the gas discharge passage 42. Accordingly, air flow directed toward the gas exhaust passage 42 is formed in the recess 66, and dust adhered to the surface of the chuck top 21 in contact with the recess 66 can be effectively removed by the air flow. Since the air flow is generated only in the cleaning wafer CW, dust does not scatter. However, in the present embodiment, the gas simply flows toward the recess 66, so that the uniformity of the cleaning is slightly poorer than that in the first embodiment.

### Third Embodiment of Cleaning Wafer

Next, a third embodiment of the cleaning wafer CW will be described.

FIG. 5 is a cross-sectional view showing a state in which the cleaning wafer CW according to the third embodiment is mounted on the chuck top 21.

The cleaning wafer CW of the present embodiment is obtained by disposing a brush 70 in a cylindrical groove-shaped recess 66 formed at the main body 61 of the cleaning wafer CW according to the second embodiment. As the brush 70, animal hair, resin fiber, nanocarbon brush or the like can be used. The brush 70 is supported by a support member 71. The support member 71 may be attached to the upper surface of the recess 66 of the main body 61, or may be fitted by a latch mechanism or the like.

Therefore, the gas introduced from the gas supply line 43 to the gas inlet line 63 in the cleaning wafer CW through the gas supply passage 41 reaches the recess 66 and flows in the recess 66 while being in contact with the brush 70. Then, the gas reaches the gas discharge passage 42 through the gas channel 67 and is discharged through the gas discharge passage 42 and the gas discharge line 44.

Thus, the gas introduced from the gas supply passage 41 to the gas inlet line 63 is supplied to the recess 66 facing the chuck top 21 and is discharged from the recess 66 through the gas channel 67 and the gas discharge passage 42. Accordingly, air flow directed toward the gas discharge passage 42 is generated in the recess 66. The brush 70 is vibrated by the air flow, and dust adhered to the surface of the chuck top 21 being in contact with the recess 66 is removed by brushing. The removed dust can be discharged by the air flow. Accordingly, strongly adhered dust can be removed, and dust can be more reliably removed. Since the air flow is generated only in the cleaning wafer CW, dust does not scatter.

### Fourth Embodiment of Cleaning Wafer

Next, a fourth embodiment of the cleaning wafer CW will be described.

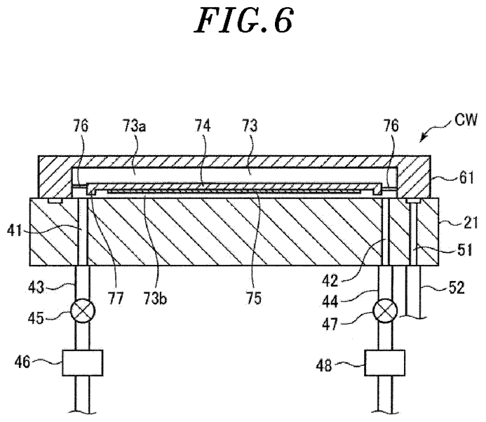

FIG. 6 is a cross-sectional view showing a state in which the cleaning wafer CW according to the fourth embodiment is mounted on the chuck top 21.

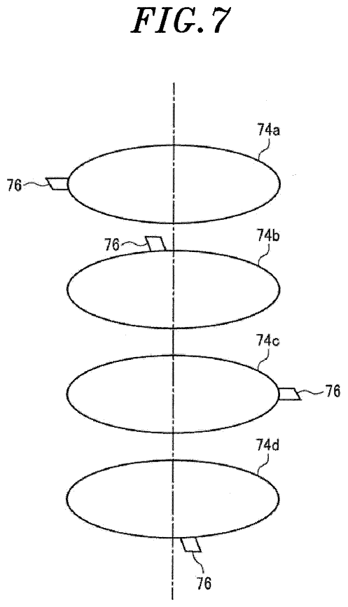

The cleaning wafer CW of the present embodiment has a main body 61 having the same disc shape as that of the wafer. At the center of the bottom surface of the main body 61, a cylindrical groove-shaped recess 73 is formed in a region including the gas supply passage 41 and the gas discharge passage 42. An elevation plate 74 formed in a disc shape having a diameter smaller than that of the recess 73 is disposed in the lower portion of the recess 73. On the bottom surface of the elevation plate 74, an adhesive film 75 such as a tack film is disposed with an adhesive surface facing the surface of the chuck top 21. The elevation plate 74 and the adhesive film form an adsorption member for adsorbing dust. A ring-shaped protrusion 77 is disposed at the outer periphery of the bottom surface of the elevation plate 74. The elevation plate 74 is connected to the main body via plate springs 76. The plate springs 76 are disposed at, e.g., four positions, and are integrated with the main body 61. Specifically, as shown in FIG. 7, the elevation plate 74 is formed by stacking and diffusion-bonding of four thin plates 74a, 74b, 74c, and 74d having the plate springs 76 directed in different directions, as will be described later. In a state where the cleaning wafer CW is attracted and held on the chuck top 21, the space formed by the recess 73 is divided into a first space 73a disposed above the elevation plate 74 and a second space 73b disposed below the elevation plate 74 by the elevation plate 74. The first space 73a is wider than the second space 73b. The recess 73 forms the inlet/outlet path.

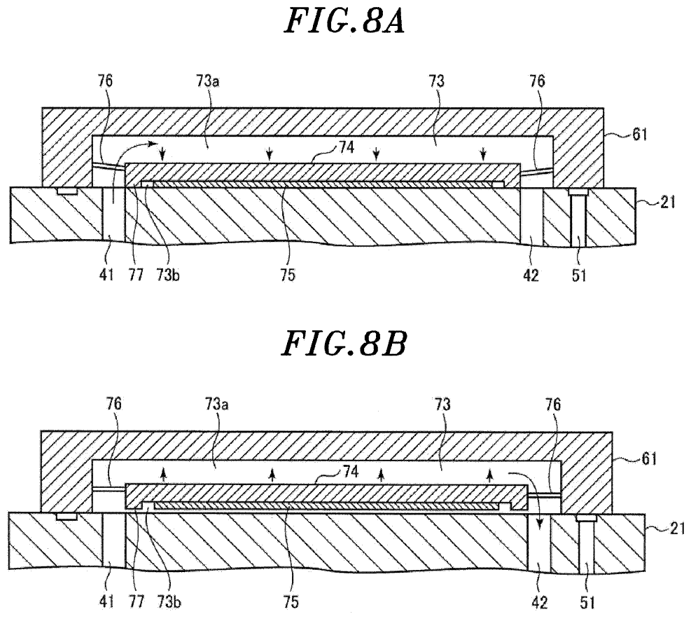

When the above-described cleaning wafer CW of the present embodiment is attracted and held on the chuck top 21 and the gas is made to flow in the recess 73 from the gas supply passage 41 toward the gas discharge passage 42, the elevation plate 74 is lowered by the gas pressure so that the ring-like protrusion 77 and the adhesive film 75 are brought into contact with the chuck top 21 as shown in FIG. 8A and the second space 73b becomes a substantially sealed space. This is because the first space 73a is wider than the second space 73b and has a conductance greater than that of the second space 73b. In this state, if the discharge of the gas is stopped while continuing the supply of the gas from the gas supply passage 41, the pressure in the first space 73a increases and the adhesive film 75 is pressed against the surface of the chuck top 21 via the elevation plate 74. Therefore, the dust adhered to the surface of the chuck top 21 is adsorbed to and removed by the adhesive film 75. Then, the supply of the gas from the gas supply passage 41 is stopped, and the discharge of the gas from the gas discharge passage 42 is started or the gas discharge amount is increased to depressurize the first space 73a. Accordingly, the elevation plate 74 is raised by the biasing force of the plate springs 76 and returned to the original position as shown in FIG. 8B. The above-described operations are performed once or multiple times.

As explained above, the cleaning wafer CW of the present embodiment has therein the recess 73. The recess 73 is used as the inlet/outlet path for discharging the gas supplied from the gas supply passage 41 to the gas discharge passage 42. In the recess 73, the elevation plate 74 having the adhesive film 75 on the bottom surface thereof is vertically movably connected to the main body 61 via the plate springs 76. By lowering the elevation plate 74 by adjusting the pressure in the recess 73, dust adhered to the surface of the chuck top 21 can be effectively adsorbed to and removed by the adhesive film 75. Since the air flow is generated only in the cleaning wafer CW, dust does not scatter.

<Method for Manufacturing Cleaning Wafer>

The cleaning wafers CW according to the first to fourth embodiments are made of metal and have a complicated structure therein. Therefore, when the cleaning wafers W are made of a bulk material, the cost increases considerably. Accordingly, it is preferable to stack a plurality of thin plates and perform heating, pressing, and diffusion bonding using diffusion of atoms.

The materials may be any material that can be bonded by diffusion bonding, and may be the same metal or different metals. For example, stainless steel, aluminum, noble metal, or the like can be used. In addition to the metal, it is also possible to use glass, a resin-based material that has been subjected to metal plating, or the like. In the fourth embodiment, the plate springs 76 are used and, thus, it is preferable to use a material suitable for the plate springs. In the case of manufacturing the cleaning wafer CW by diffusion bonding, thin plates are stacked and punched into a predetermined shape, and then are diffusion-bonded to form the shapes of the first to the fourth embodiment. The thin plates have a thickness of about 0.005 mm to 5 mm.

Due to the diffusion bonding, the complicated processing such as processing of a bulk material or the like becomes unnecessary, and the cleaning wafer can be manufactured with high accuracy without slipping out of the adhesive unlike the case of performing bonding using an adhesive.

As described above, it is preferable to manufacture the cleaning wafer by performing diffusion bonding of a metal-based material or the like. However, it is also possible to manufacture the cleaning wafer by bonding a material, e.g., a resin-based material such as rubber or the like, other than the metal-based material, using an adhesive.

<Other Applications>

While several embodiments of the present invention have been described, the present invention is not limited thereto, and can be variously modified without departing from the gist of the present invention.

For example, the above embodiments have described the case where the present invention is applied to the inspection system including a plurality of inspection devices. However, the present invention is not limited thereto, and the stage cleaning member (cleaning wafer) of the present invention may be applied to a single inspection device.

Further, the above embodiments have described the case where the present invention is applied to the wafer inspection device. However, the present invention is not limited to the inspection device as long as it includes a stage for attracting and holding a substrate. The substrate as a processing target is not limited to the semiconductor wafer, and various substrates can be used.

### DESCRIPTION OF REFERENCE NUMERALS

10: inspection system
21: chuck top
23: probe card
23a: probe
30: inspection device
41: gas supply passage
42: gas discharge passage
51: gas exhaust passage
61: main body
62: gas diffusion space
63: gas inlet line
64, 66, 73: recess
65: gas injection hole
67: gas channel
70: brush
73a: first space
73b: second space
74: elevation plate
75: adhesive film
76: plate spring
77: protrusion
CW: cleaning wafer (stage cleaning member)
W: semiconductor wafer (substrate)

1. A stage cleaning member for cleaning a surface of a stage by being mounted on the stage, the stage having a gas supply port and a gas exhaust port on the surface thereof and being configured to mount a substrate thereon, comprising:
a plate-shaped main body; and
an inlet/outlet path disposed in the main body, to which gas is supplied from the gas supply port and from which the gas is exhausted to the gas exhaust port,
wherein dust adhered to the surface of the stage is removed by the gas being supplied to the inlet/outlet path and exhausted from the inlet/outlet path.

2. The stage cleaning member of claim 1, wherein the main body is vacuum-attracted to the stage.

3. The stage cleaning member of claim 1, wherein the inlet/outlet path includes a recess formed below a bottom surface of the main body in a situation of being mounted on the stage, and
dust adhered to the surface of the stage which corresponds to the recess is removed by air flow that is generated in the recess when the gas is supplied from the gas supply port to the recess and exhausted from the recess to the gas exhaust port.

4. The stage cleaning member of claim 3, wherein the inlet/outlet path further includes a gas diffusion space formed in the main body to allow diffusion of the gas supplied from the gas supply port and a plurality of gas injection holes for injecting the gas from the gas diffusion space to the recess, and
the dust adhered to the surface of the stage which corresponds to the recess is removed by the air flow supplied from the gas diffusion space to the recess through the gas injection holes and discharged to the gas exhaust port.

5. The stage cleaning member of claim 3, further comprising:
a brush disposed in the recess,
wherein the brush is vibrated by the air flow that is generated in the recess when the gas is supplied from the gas supply port to the recess and exhausted from the recess to the gas exhaust port,
the dust adhered to the surface of the stage which corresponds to the recess is removed by a vibration of the brush, and
the removed dust is discharged to the gas exhaust port by the air flow generated in the recess.

6. The stage cleaning member of claim 1, wherein the inlet/outlet path includes a recess formed below a bottom surface of the main body in a situation of being mounted on the stage and an adsorption member which is disposed in the recess and has an adsorption surface facing the surface of the stage, and
the adsorption member is vertically moved by adjusting supply of the gas from the gas supply port to the inlet/outlet path or exhaust of the gas from the gas exhaust port to adsorb and remove the dust adhered to the surface of the stage.

7. The stage cleaning member of claim 6, wherein the adsorption member has an elevation plate and an adhesive film formed on a bottom surface of the elevation plate, and
the dust adhered to the surface of the stage is adsorbed to and removed by the adhesive film.

8. The stage cleaning member of claim 7, wherein the elevation plate is connected to the main body via plate springs and is vertically moved via the plate springs.

9. A stage cleaning method for cleaning a surface of a stage, the stage having a gas supply port and a gas exhaust port on the surface and being configured to mount a substrate thereon, the method comprising:
mounting a stage cleaning member on the stage, the stage cleaning member having a plate-shaped main body and an inlet/outlet path to which gas is supplied from the gas supply port and from which the gas is exhausted to the gas exhaust port, the inlet/outlet path being disposed in the main body; and
removing dust adhered to the surface of the stage using the gas being supplied to the inlet/outlet path and exhausted from the inlet/outlet path.

10. The stage cleaning method of claim 9, wherein the main body of the stage cleaning member is vacuum-attracted to the stage to remove the dust adhered to the surface of the stage.

11. The stage cleaning method of claim 9, wherein the inlet/outlet path of the stage cleaning member includes a recess formed below a bottom surface of the main body in a situation of being mounted on the stage, and
dust adhered to the surface of the stage which corresponds to the recess is removed by air flow that is generated in the recess when the gas is supplied from the gas supply port to the recess and exhausted from the recess to the gas exhaust port.

12. The stage cleaning method of claim 11, wherein the inlet/outlet path of the stage cleaning member further includes a gas diffusion space formed in the main body to allow diffusion of the gas supplied from the gas supply port and a plurality of gas injection holes for injecting the gas from the gas diffusion space to the recess, and
the dust adhered to the surface of the stage which corresponds to the recess is removed by the air flow supplied from the gas diffusion space to the recess through the gas injection holes and exhausted to the gas exhaust port.

13. The stage cleaning method of claim 11, wherein a brush is disposed in the recess,
the brush is vibrated by the air flow that is generated in the recess when the gas is supplied from the gas supply port to the recess and exhausted from the recess to the gas exhaust port,
the dust adhered to the surface of the stage is removed by a vibration of the brush, and
the removed dust is discharged to the gas exhaust port by the air flow generated in the recess.

14. The stage cleaning method of claim 9, wherein the inlet/outlet path of the stage cleaning member includes a recess formed below a bottom surface of the main body in a situation of being mounted on the stage and an adsorption member which is disposed in the recess and has an adsorption surface facing the surface of the stage, and
the adsorption member is vertically moved by adjusting supply of the gas from the gas supply port to the inlet/outlet path or exhaust of the gas from the gas exhaust port to adsorb and remove the dust adhered to the surface of the stage.

15. The stage cleaning method of claim 14, wherein the adsorption member has an elevation plate and an adhesive film formed on a bottom surface of the elevation plate, and
the dust adhered to the surface of the stage is adsorbed to and removed by the adhesive film.

16. The stage cleaning method of claim 15, wherein the elevation plate is connected to the main body via plate springs and is vertically moved via the plate springs.

17. A method for producing the stage cleaning member described claim 1, wherein a plurality of thin plates are formed in a predetermined shape, stacked, and diffusion-bonded by heating and pressing to form the stage cleaning member having a desired shape.

18. An inspection system, comprising:
an inspection device having a stage which is configured to mount a substrate thereon and being configured to inspect the substrate on the stage;
a substrate accommodation part configured to accommodate the substrate;
a stage cleaning member accommodation part configured to accommodate a stage cleaning member for cleaning a surface of the stage by being mounted on the stage, the stage having a gas supply port and a gas exhaust port on the surface thereof and being configured to mount a substrate thereon, the stage member comprising:
a plate-shaped main body, and
an inlet/outlet path disposed in the main body, to which gas is supplied from the gas supply port and from which the gas is exhausted to the gas exhaust port, wherein dust adhered to the surface of the stage is removed by the gas being supplied to the inlet/outlet path and exhausted from the inlet/outlet path; and
a transfer device configured to transfer the substrate accommodated in the substrate accommodation part and the stage cleaning member accommodated in the stage cleaning member accommodation part onto the stage,
wherein
the stage cleaning member is transferred onto the stage by the transfer device when cleaning the surface of the stage.
